(19) United States
(12) Patent Application Publication
(10) Pub. No.: US 2010/0287447 A1
(43) Pub. Date: Nov. 11, 2010

(54) MEMORY SYSTEM IDENTIFYING AND CORRECTING ERASURE USING REPEATED APPLICATION OF READ OPERATION

(75) Inventors: Hee Seok EUN, Hwaseong-si (KR); Jae Hong KIM, Seoul (KR); Seung-Hwan SONG, Suwon-si (KR); Ho-Chul LEE, Seoul (KR); Yong June KIM, Seoul (KR); Han Woong YOO, Seoul (KR); Jun Jin KONG, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/773,179

(22) Filed: May 4, 2010

(30) Foreign Application Priority Data
May 7, 2009 (KR) 10-2009-0039906

(51) Int. Cl. H03M 13/05; G06F 11/10

(52) U.S. Cl. 714/763; 714/E11.034

(57) ABSTRACT

Provided is a read method for a memory system. The read method determines whether a read data error is correctable. The read method applies a plurality of read operations at a set read voltage level to identify erasure candidates, when the error is uncorrectable. The read method performs erasure decoding using an error correction code or an error detection code for the erasure candidates.

### CROSS-REFERENCE TO RELATED APPLICATIONS

This U.S. non-provisional patent application claims priority under 35 U.S.C. §119 to Korean Patent Application No. 10-2009-0039906 filed on May 7, 2009, the subject matter of which is hereby incorporated by reference.

### BACKGROUND

The present disclosure relates to memory systems and methods of identifying and/or resolving ambiguously stored data (erasure candidates) using repeated application of a read operation at a defined read voltage level.

Semiconductor memory devices may be divided into volatile and nonvolatile types. Although the read/write speed of volatile semiconductor memories is fast, stored data may be lost when applied power is interrupted. In contrast, nonvolatile semiconductor memories retain stored data in the absence of applied power. Therefore, nonvolatile semiconductor memories are used to store data that must be retained irrespective of the external power supply.

Volatile memory includes Dynamic Random Access Memory (DRAM) or Static Random Access Memory (DRAM). Nonvolatile memory includes NAND and NOR flash memory, Phase change Random Access Memory (PRAM), etc.

Unlike MROM, PROM and EPROM, EEPROM may be electrically erased and programmed. Therefore, it is used within many systems and auxiliary memory devices requiring a continuous update. Particularly, because flash EEPROM has a higher degree of integration than the existing EEPROM, it may be very easily applied as large-capacity auxiliary memory devices. Among flash EEPROM, NAND-type flash EEPROM has a far higher degree of integration than other flash EEPROM.

Recently, as high-integration requirements for memory devices increase, multi-bit memory devices that store multi bits in one memory cell are being generalized. In the memory cells of a multi-bit flash memory device, the intervals between threshold voltage distributions should be densely controlled. That is, data retention characteristics and the number of programming/erasion cycles (or durability) in which quality is not degraded are the most important issues in association with reliability.

As the size of various semiconductor memory devices decrease and operation voltages become lower, data read errors due to noise, such as thermal noise and Random Telegraph Signal (RTS) noise, have increased.

### SUMMARY

Embodiments of the inventive concept provide memory systems and methods of reading data in a memory system that decrease data read errors, such as those caused by memory system noise.

Embodiments of the inventive concept provide a read method performed in a memory system, the read method comprising; determining whether or not an error detected in read data retrieved from a memory is correctable, if the read data error is not correctable, determining whether or not the read data error is an erasure by repeatedly applying a read operation to a memory cell in the memory associated with the read data error, wherein the read operation is repeatedly applied at a reference voltage level, and upon determining that the read data error is not correctable and is an erasure, performing an erasure decoding on the read data error.

Embodiments of the inventive concept also provide a read method comprising; reading data from a memory, applying a plurality of read operations to the read data using a set read voltage to identify erasure candidates, performing erasure manipulation for all of the erasure candidates, and determining whether or not an error in the read data is correctable following erasure manipulation.

Embodiments of the inventive concept also provide a memory system, comprising; a memory, and an error correction circuit configured to detect/correct an error in read data retrieved form the memory, wherein the error correction circuit is configured to apply a plurality of read operations at a set read voltage level to identify erasure candidates in the read data.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating a memory system according to an exemplary embodiment of the inventive concept;

FIG. 2 is a diagram illustrating an erasure selection method according to an exemplary embodiment of the inventive concept;

FIG. 3 is a diagram for describing the reason in which it is difficult to perform bit decision;

FIG. 4 is a flow chart illustrating the reading method of the memory system in FIG. 1, according to an exemplary embodiment of the inventive concept;

FIG. 5 is a flow chart illustrating the reading method of the memory system in FIG. 1, according to another exemplary embodiment of the inventive concept;

FIG. 6 is a block diagram illustrating a memory system according to another exemplary embodiment of the inventive concept;

FIG. 7 is a flow chart illustrating the reading method of the memory system in FIG. 6, according to an exemplary embodiment of the inventive concept;

FIG. 8 is a flow chart illustrating the reading method of the memory system in FIG. 6, according to another exemplary embodiment of the inventive concept;

FIG. 9 is a block diagram illustrating a memory according to an exemplary embodiment of the inventive concept;

FIG. 10 is a block diagram illustrating a memory according to another exemplary embodiment of the inventive concept;

FIG. 11 is a block diagram illustrating an exemplary embodiment of a Solid State Disk (SSD) to which embodiments of the inventive concept are applied;

FIG. 12 is a block diagram illustrating a memory system according to another exemplary embodiment of the inventive concept; and

FIG. 13 is a block diagram illustrating a memory system according to another exemplary embodiment of the inventive concept.

### DETAILED DESCRIPTION OF THE EMBODIMENTS

Exemplary embodiments of the inventive concept will now be described below in some additional detail with reference to the accompanying drawings. The inventive concept may, however, be embodied in different forms and should not be construed as being limited to only the illustrated embodiments. Rather, the embodiments are presented as teaching examples.

A memory system according to embodiments of the inventive concept is capable of addressing an erasure by iteratively performing a read operation at a certain voltage level. In this context the term “erasure” denotes an ambiguous data state for a programmed memory cell which it is difficult to interpret. For example, assuming a binary memory cell an erasure will make it difficult to interpret within a conventional memory system whether a logic value of ‘0’ or ‘1’ should be read from the memory cell during a read operation. However, a memory system according to embodiment of the inventive concept performs some additional error correction processing on the basis of a selected erasure. This additional error correction processing decreases read errors during the read operation.

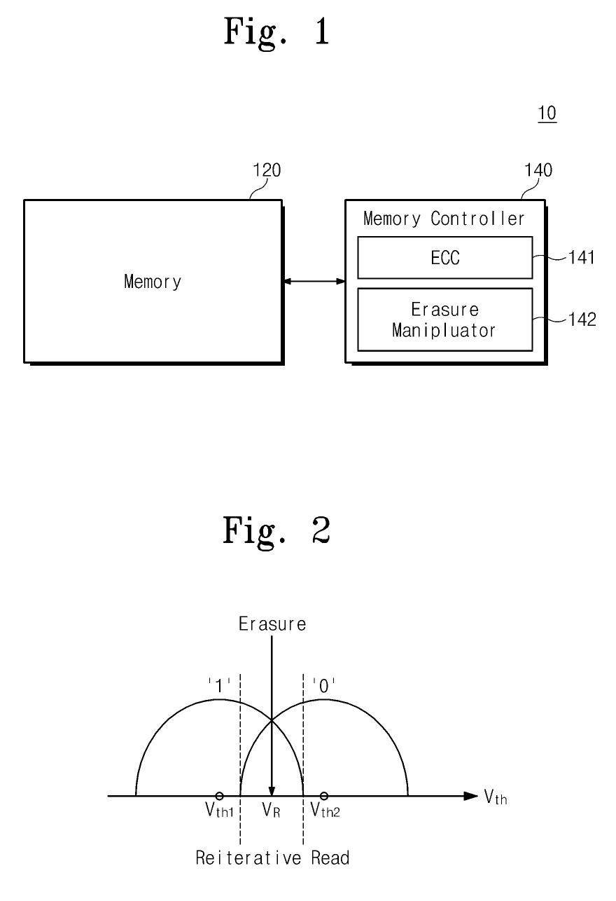

Figure (FIG. 1 is a general block diagram of a memory system according to an embodiment of the inventive concept.

Referring to FIG. 1, a memory system 10 comprises a memory 120 and a memory controller 140 configured to control the memory 120 and incorporating an erasure manipulator 142, in addition to an error detection/correction circuit (ECC) 141. This type of memory controller including an erasure manipulator 142 is capable of selecting an erasure and then more accurately reading the ambiguously stored data by iteratively performing a read operation at a certain voltage level.

The memory 120 may be any device configured to store data on the basis of stored electrical charge. That is, the memory 120 may be volatile or nonvolatile in its operation. Alternately, the memory 120 may be a device configured to store data by means other than stored electrical charge.

The ECC 141 may be substantially conventional in its internal configuration and operation according to a broad class of circuits, software, and firmware capable of detecting and/or correcting errors in data read from memory 120. As is well understood by those skilled in the art, error in the data read from memory 120 may be detected and/or corrected using error correction code stored in the memory in relation to payload (e.g.,) user data. Such error correction code may be generated in one of many forms including as examples, Reed-Solomon code, BCH code, binary Golay code, binary Goppa code, or a Viterbi. The data errors detected and/or corrected by the error correction circuit 140 may generated by various anomalies (structural or functional) within the memory system 10, including certain well understood noise effects that may arise during the writing/programming of data to the memory 120.

However, the error correction circuit 141 within certain embodiments of the inventive concept may perform error correction operation(s) using error correction code that has been manipulated by the erasure manipulator 142 when a detected error cannot be corrected using so-called hard decision decoding. In this context the term “hard decision” denotes a non-ambiguous or firm decision making process wherein an ambiguous data state is, by fixed rule, resolved as a specified default state.

Recognizing that it is not always possible or practical to resolve an ambiguous data state using a hard decision decoding process, embodiments of the inventive concept provide for the resolution of an ambiguous read data state using a technique that will hereafter be referred as “erasure manipulation”. As a result, the ECC 141 may provide greater error correction capabilities than conventional memory systems relying solely on hard decision decoding.

Conventional memory systems are often limited in their ability to correct detected data errors. For example, the use of associated error correction code is only possible when distinctively errant payload data is processed in relation to the error correction code. Where said payload data is an ambiguous erasure (i.e., maybe either a ‘1’ or ‘0’ in a binary memory cell based memory system) rather than being errantly distinct, the ECC capabilities provided by conventional memory systems may be unable to resolve the ambiguous data, other than merely assigning a default data value according to some hard decision decoding rule.

In contrast, the memory system 10 according to an embodiment of the inventive concept is capable of additionally selecting and manipulating the erasure, instead of merely seeking to correct the erasure using error correction code or a hard decision decoding rule in order to improve the overall error correction capabilities of the system. More particularly, the memory system 10 iteratively performs a read operation at the same voltage level after selecting the erasure to thereby decrease errors in the read data, such as those caused by transient noise.

In operation, the erasure manipulator 142 selects an erasure and then iteratively performs a read operation at the same voltage level to appropriately decode the erasure and then communicate the manipulated erase read output to the decoder of the error correction code, typically circuitry or firmware resident in the ECC 141. In the illustrated embodiment of FIG. 1, the erasure manipulator 142 is disposed within the memory controller 140, but memory systems according to embodiments of the inventive concept are not limited thereto. The erasure manipulator 142 may be implemented in software as a control algorithm or in hardware (or firmware) as internally included within the memory controller 140, or as externally provided outside the memory controller 140.

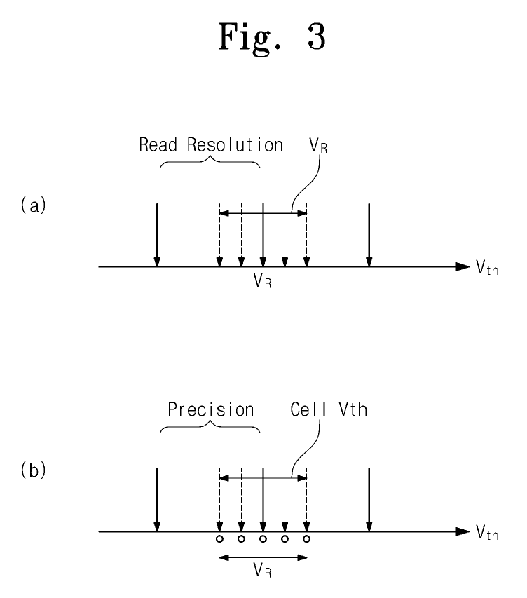

FIG. 2 is a conceptual diagram illustrating an exemplary erasure selection approach by the erasure manipulator 142 of FIG. 1 assuming a binary memory cell.

Referring to FIG. 2, during a bit decision process, it will be determined whether a selected memory cell has (1) a distinct logic state of ‘1’; (2) a distinct logic state of ‘0’; or (3) an ambiguous (or erasure) state. An accurate bit decision process may be achieved when the resolution and precision of an applied read voltage V_{R} is high.

As conceptually shown in FIG. 3(a), the read operation may not be performed in any greater detail because of clear limitations in the read resolution capabilities. Moreover, as conceptually shown in FIG. 3(b), because of the clear limitations in precision or variation in memory cell distribution voltage certain physical errors may arise. And due to these conditions (e.g.), it may be difficult to perform accurate bit decision making during a read operation.

However, within embodiments of the inventive concept an erasure may be selected for additional processing using an accurate bit decision making An erasure selection method according to an exemplary embodiment of the inventive concept selects the erasure by iteratively performing a read operation at a reference voltage level V_{R}. That is, the erasure is selected as the results of a plurality of read operations using the same reading voltage level. For example, the erasure may be selected using a number of logic state flips. A “flip” denotes a case wherein upon performing the read operation using the same voltage level, a first logic sate (e.g., ‘1’) is determined during a first iteration, and a second logic state (e.g., ‘0’) is determined during a next (or second) iteration of the read operation.

There are many different ways to use the detected occurrence of one or more flips to identify an erasure. For example, if a flip is generated when a read operation is twice performed, then the bit decision for the corresponding memory cell may be an erasure. Alternately, if the frequency of first logic to second logic for a repeatedly read memory cell is 2:1 or less for three or more read operations, the bit decision for the corresponding memory cell may be an erasure. Those skilled in the art will recognize that many other conditions may be defined to identify an erasure based on the repeated application of a read operation using a set (and substantially constant) voltage level.

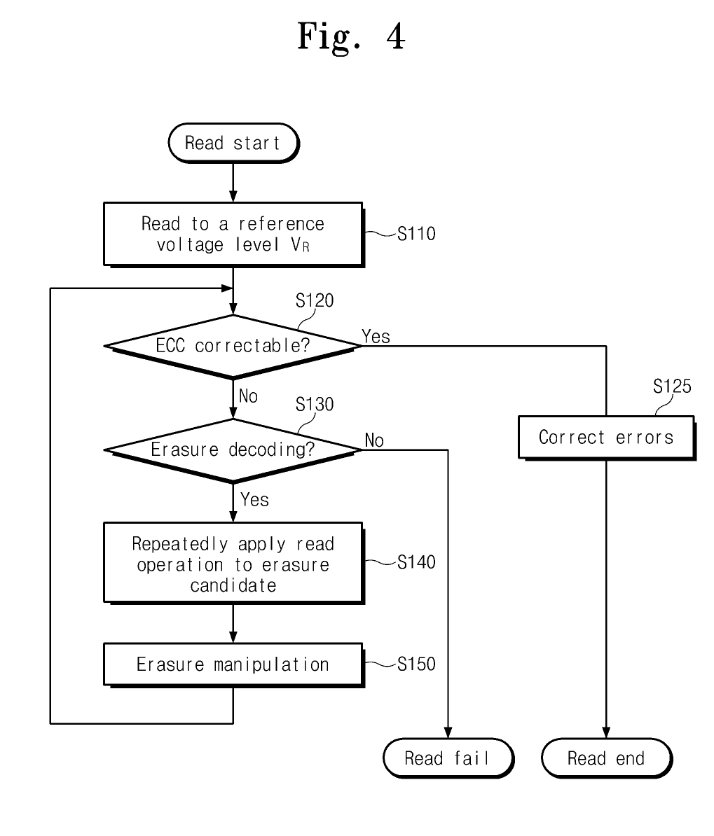

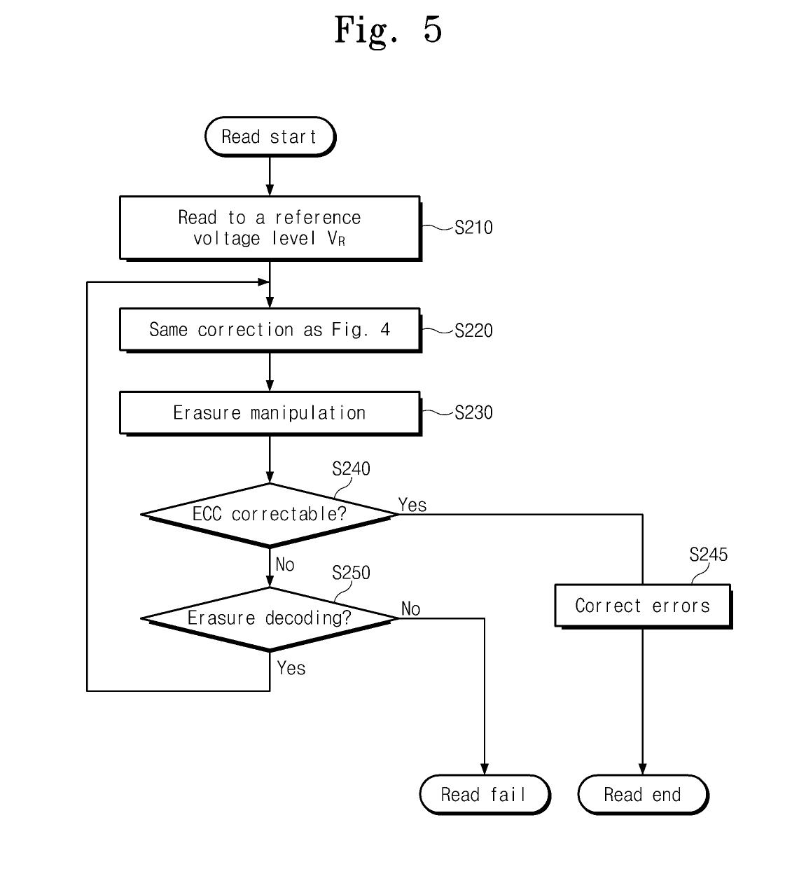

FIG. 4 is a flowchart summarizing a read operation performed in the memory system of FIG. 1 according to an embodiment of the inventive concept. Referring to FIGS. 1 through 4, the exemplary read operation may be performed as follows.

Data is read from the memory 120 using a reference voltage level V_{R} in response to an external read request received in memory system 10 (S110). At this point, the “read data” retrieved from the memory 120 in response to the read request is communicated to ECC 140. The ECC 140 then performs an error detection/correction operation in relation to the read data. During ECC processing, it is first determined whether an error is present in the read data (assumed in the illustrated example) and whether the detected error is correctable (S120). If it is determined that the detected error is correctable using the capabilities routinely provided by the ECC 140 (S120=YES), the detected error is corrected (S125).

However, if it is determined that the detected error is not correctable (S120=NO), erasure decoding of the read data should be performed (S130). Uncorrectable read data may arise due to a number of different causes. Erasure decoding determines whether the detected error is uncorrectable because it is not errantly distinct but is ambiguous. If the uncorrectable read data is not the result of an erasure (S130=NO), then a read fail in indicated by the memory controller 140.

To perform erasure decoding (S130=YES), a possible erasure (i.e., an erasure candidate) is selected to receive repeated application of a read operation using the same reference voltage level V_{R} (S140). Herein, the detection of an erasure may be accomplished as described above in relation to FIG. 2. Subsequently, operation of the erasure manipulator 142 may be invoked to manipulate the selected erasure (S150). By means of the erasure manipulator 142, the read method may alter the data value of all erasure candidates to either ‘1’ or ‘0’ thereby ensuring that erasure decoding is fully performed in a next iteration of the read operation loop.

Herein, an erasure manipulation method may be variously implemented. As an example, all the logic states of the selected erasure candidates may be decoded into logic ‘1’ or logic ‘0’. As another example, bit change may be performed on the read data or on the erasure candidates. The erasure manipulation method according to an exemplary embodiment of the inventive concept is not limited to the above-described embodiments, and may be various combined and used. In this way, after erasure manipulation is terminated, operation S120 is again performed.

FIG. 5 is another flow chart summarizing the performance of a read operation within the memory system of FIG. 1 according to another embodiment of the inventive concept. Referring to FIGS. 1, 2 and 5, a variation on the read operation previously described will be explained.

The method summarized in FIG. 5 is essentially the same as that described in FIG. 4, except the order of the constituent steps has been changed. That is, erasure detection (S220) and erasure manipulation (S230) are always applied to the read data, before a determination of correctability (S240) and erasure decoding (S250) are performed. The method steps of FIG. 5 may otherwise be performed like their analogous counterparts in the method of FIG. 4.

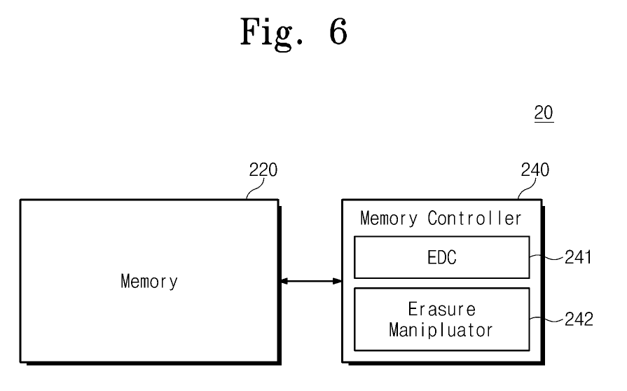

FIG. 6 is general block diagram of a memory system according to another embodiment of the inventive concept.

Referring to FIG. 6, a memory system 20 comprises a memory 220 and a memory controller 240 configured to control the memory 220. However, the memory controller 240 comprises an Error Detection Circuit (EDC) 241 capable of detecting one or more error(s) in read data retrieved from the memory 220, and an erasure manipulator 242 capable of identifying erasure(s) among the detected errors by repeatedly performing a read operation at a defined voltage level.

The EDC correction circuit 241 may detect an error in the read data using conventional error detection techniques, such as those associated with parity bits or error correction code. The EDC 241 may additionally perform an erasure decoding operation on a detected read data error using erasure manipulation.

Here again, the erasure manipulator 242 of FIG. 6 may be disposed inside the memory controller 240, but the memory system according to another exemplary embodiment of the inventive concept is not limited thereto. The erasure manipulator 242 may be implemented in software, firmware and/or hardware included within or provided external to the memory system 20.

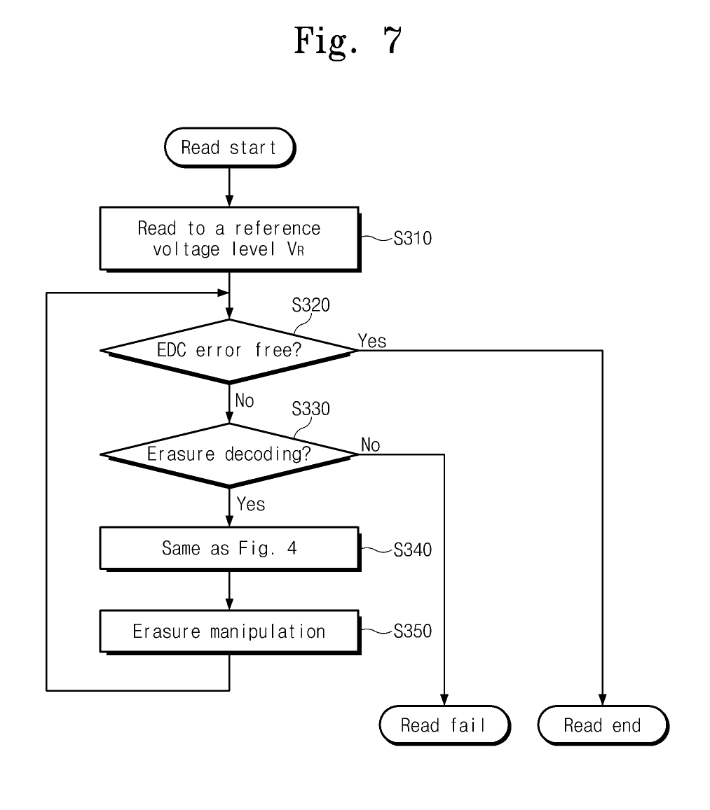

FIG. 7 is a flowchart illustrating a read operation performed in the memory system of FIG. 6 according to another embodiment of the inventive concept.

Referring to FIGS. 6 and 7, data is read from the memory 220 using a reference voltage level V_{R} in response to a read request received by the memory system 20 (S310). At this point, the read data are transferred to the EDC 240. The EDC 240 performs an error detection operation on the read data to determine whether an error exists in the read data (S320). If not, the read operation is completed.

However, if a read data error is identified, a determination is made as to whether the detected error in the read data is an erasure (i.e., an erasure decoding routine is performed S330). Thus, the erasure decoding operation acts as a type of error correction operation. However, if the detected read data error is not susceptible to erasure decoding correction a read fail may result.

To perform erasure decoding, erasure candidates are selected by repeatedly performing a read operation at the reference voltage level V_{R} (S340). Subsequently, the erasure manipulator 242 may manipulate an erasure using the selected erasure candidates (S350). After erasure manipulation is completed, the routine loops back to step S320.

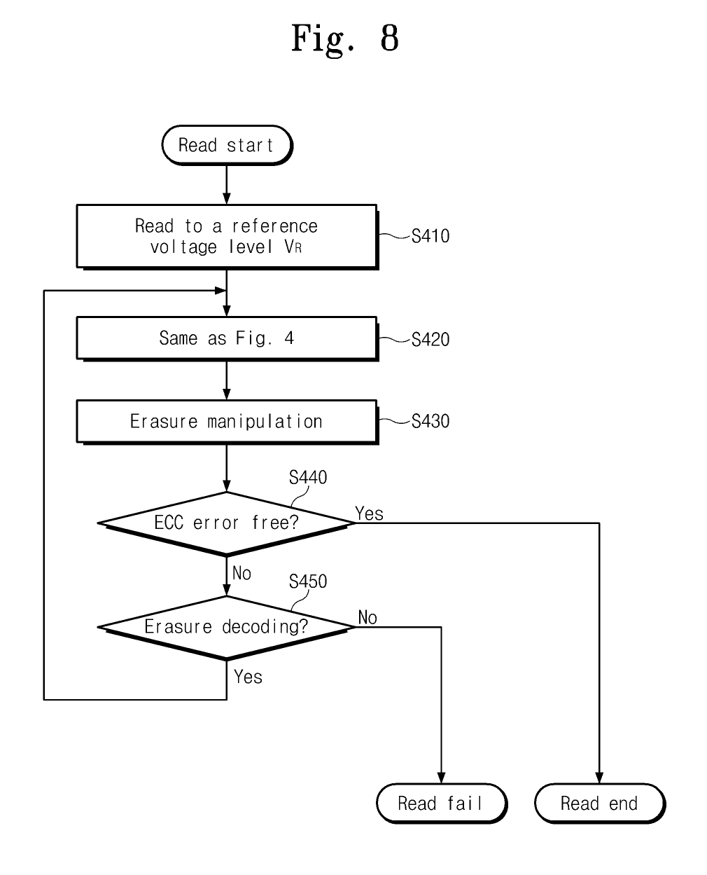

FIG. 8 is a flowchart illustrating the read operation of the memory system in FIG. 6 according to another exemplary embodiment of the inventive concept. Referring to FIGS. 6 and 8, the read operation of FIG. 7 is reordered as shown. That is, error detection by the EDC (S420) and erasure decoding (S450) are performed after erasure identification and manipulation (S420 and S430).

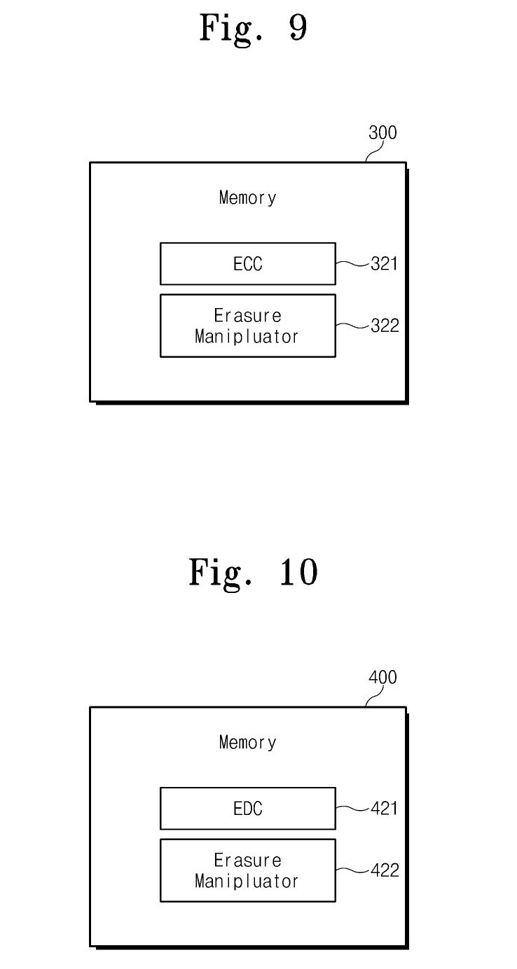

Exemplary embodiments of the inventive concept are not limited to memory systems. The inventive concept, as illustrated in FIG. 9, may include the error correction code 321 and the erasure manipulator 322 inside the memory 300, or, as illustrated in FIG. 10, the inventive concept may include the error detection circuit 421 and the erasure manipulator 422 of FIG. 6.

The memory system according to exemplary embodiments of the inventive concept may be applied to a Solid State Disk (SSD).

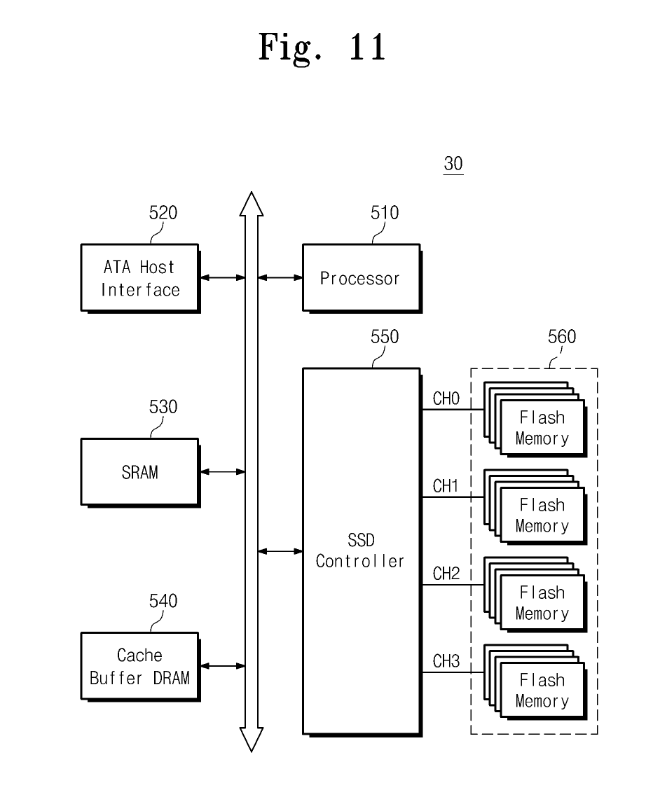

FIG. 11 is a block diagram illustrating an SSD memory system according to an exemplary embodiment of the inventive concept.

Referring to FIG. 11, an SSD memory system 500 according to an exemplary embodiment of the inventive concept includes an SSD controller 550 and flash memories 560. The SSD controller 550 may be implemented to have the function of the error correction circuit 140 in FIG. 1 or to have the function of the error detection circuit 240 in FIG. 6.

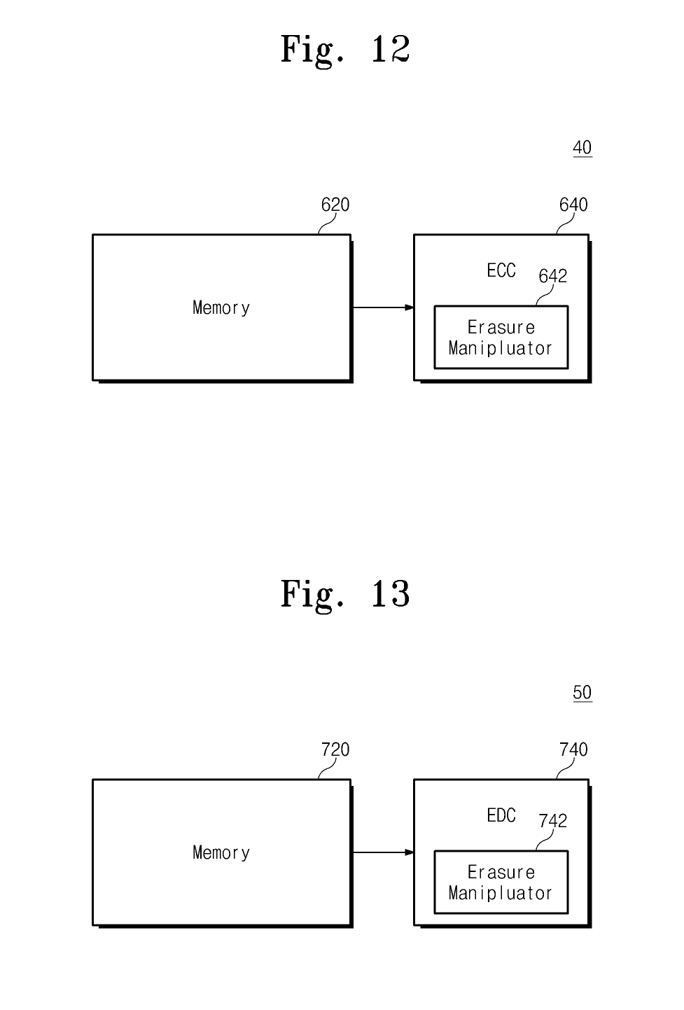

Referring again to FIG. 12, a processor 510 receives a command from a host to determine and control whether it stores data from the host in a flash memory or reads the stored data of the flash memory to transmit the read data to the host.

An ATA host interface 520 exchanges data with the host according to the control of the processor 510. The ATA host interface 520 fetches a command and an address from the host and transfers the command and address to the processor 510 through a CPU bus 510. Herein, the ATA host interface 520 may be any one of SATA interface, PATA interface and External SATA (ESATA) interface.

Data that are inputted from the host through the ATA host interface 520 or data to be transmitted to the host are transferred through a cache buffer RAM 540 without passing through the CPU bus according to the control of the processor 510.

An RAM 530 is used to temporarily store data necessary for the operation of the flash memory system 500. As a volatile memory device, the RAM 530 may be DRAM or SRAM.

The cache buffer RAM 540 temporarily stores mobile data between the host and the flash memories 560. Moreover, the cache buffer RAM 540 is used to store programs to be operated by the processor 510. The cache buffer RAM 540 may be regarded as a kind of buffer memory, and may be implemented with SRAM.

The SSD controller 550 exchanges data with flash memories that are used as storages. The SSD controller 550 may be configured to support a NAND flash memory, a One-NAND flash memory, a multi level flash memory and a single level flash memory.

An erasure manipulator according to an exemplary embodiment of the inventive concept may be included in an error correction circuit or an error detection circuit. FIG. 12 is a diagram illustrating a memory system 40 in which an erasure manipulator 642 according to an exemplary embodiment of the inventive concept is included in an Error Correction Circuit (ECC) 640. FIG. 13 is a diagram illustrating a memory system 50 in which an erasure manipulator 742 according to another exemplary embodiment of the inventive concept is included in an Error Detection Circuit (EDC) 740.

The memory system according to exemplary embodiments of the inventive concept may be used as a mobile storage device. Accordingly, the memory system may be used as the storage of MP3, the storages of digital cameras, the storages of Personal Digital Assistants (PDA) and the storages of e-Books.

The memory system and/or the memory device according to exemplary embodiments of the inventive concept may be mounted with various types of packages. For example, the memory system and/or the memory device according to exemplary embodiments of the inventive concept may be mounted with packages such as Package on Package (PoP), Ball Grid Arrays (BGAs), Chip Scale Packages (CSPs), Plastic Leaded Chip Carrier (PLCC), Plastic Dual In-Line Package (PDIP), Die In Waffle Pack (DIWP), Die In Wafer Form (DIWF), Chip On Board (COB), Ceramic Dual In-Line Package (CERDIP), Plastic Metric Quad Flat Pack (MQFP), Thin Quad Flat Pack (TQFP), Small Outline Package (SOP), Shrink Small Outline Package (SSOP), Thin Small Outline Package (TSOP), Thin Quad Flat Pack (TQFP), System In Package (SIP), Multi Chip Package (MCP), Wafer Level Stack Package (WLSP), Die In Wafer Form (DIWF), Die On Waffle Package (DOWP), Wafer-level Fabricated Package (WFP) and Wafer-Level Processed Stack Package (WSP).

As described above, the memory system according to embodiments of the inventive concept identifies erasure(s) by repeatedly performing a read operation at the same (reference) voltage level when a detected read data error is deemed uncorrectable, and can correct said read data error, as caused by the identified erasure. Accordingly, memory systems according to embodiments of the inventive concept improve memory system error correction capabilities, and consequently, provide a reduced number of read data errors.

The above-disclosed subject matter is to be considered illustrative and not restrictive, and the appended claims are intended to cover all such modifications, enhancements, and other embodiments, which fall within the scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A read method performed in a memory system, the read method comprising:
determining whether or not an error detected in read data retrieved from a memory is correctable;
if the read data error is not correctable, determining whether or not the read data error is an erasure by repeatedly applying a read operation to a memory cell associated with the read data error, wherein the read operation is repeatedly applied at a defined reference voltage level; and
upon determining that the read data error is not correctable and is an erasure, performing an erasure decoding to correct the read data error.

2. The read method of claim 1, wherein the erasure decoding is performed using at least one of error correction code and error detection code associated with the read data error.

3. The read method of claim 2, further comprising:
again determining whether or not the read data error is correctable following performance of the erasure decoding.

4. The read method of claim 1, wherein determining whether the read data error is an erasure comprises:
repeatedly applying the read operation and determining whether a data value flip is generated.

5. The read method of claim 1, further comprising:
after performing the erasure decoding, performing an erasure manipulation.

6. The read method of claim 1, wherein all erasure candidates are corrected to be a distinct logic state by the erasure manipulation.

7. A read method in a memory system, the method comprising:
reading data from a memory;
applying a plurality of read operations to the read data using a set read voltage to identify erasure candidates;
performing erasure manipulation for all of the erasure candidates; and
determining whether or not an error in the read data is correctable following erasure manipulation.

8. The read method of claim 7, further comprising:
if the read data error is determined to not be correctable, performing an erasure decoding.

9. The read method of claim 8, wherein the erasure decoding is performed using error correction code or error detection code associated with the read data including the erasure.

10. The read method of claim 8, further comprising:
after performing the erasure decoding, again performing the erasure manipulation.

11. The read method of claim 10, wherein all erasure candidates are corrected to be a distinct logic state by the erasure manipulation.

12. A memory system, comprising:
a memory; and
an error correction circuit configured to detect/correct an error in read data retrieved from the memory, wherein the error correction circuit is configured to apply a plurality of read operations at a set read voltage level to identify erasure candidates in the read data.

13. The memory system of claim 8, wherein:
the error correction circuit is further configured to determine whether the read data error is correctable using an error correction code.

14. The memory system of claim 13, further comprising:
if the read data error is uncorrectable, the error correction circuit is further configured to apply the plurality of read operations to identify the erasure candidates, and thereafter to manipulate an erasure among the erasure candidates.

15. The memory system of claim 14, wherein the erasure candidates are identified in relation to logic state flips in response to the repeated application of the read operation.
